(19) United States
(12) Patent Application Publication
(10) Pub. No.: US 2022/0158103 A1
(43) Pub. Date: May 19, 2022

(54) OPTICAL SENSOR

(71) Applicant: Panasonic Intellectual Property Management Co., Ltd., Osaka (JP)

(72) Inventors: YUKO KISHIMOTO, Osaka (JP); MITSURU HARADA, Osaka (JP); HIROAKI IIJIMA, Nara (JP)

(21) Appl. No.: 17/649,559

(22) Filed: Feb. 1, 2022

Related U.S. Application Data
(63) Continuation of application No. PCT/JP2020/029369, filed on Jul. 31, 2020.

(30) Foreign Application Priority Data
Aug. 21, 2019 (JP) 2019-151422

(51) Int. Cl. H01L 51/42; H01L 51/44

(52) U.S. Cl. CPC H01L 51/428; H01L 51/441

(57) ABSTRACT

An optical sensor includes a substrate, a photoelectric conversion layer, a first electrode, and a second electrode. The photoelectric conversion layer has a first surface facing the substrate, a second surface located opposite the first surface, and at least one side surface connecting the first surface with the second surface. The photoelectric conversion layer is supported by the substrate. The first electrode includes a first portion and a second portion separated from the first portion. The second portion is closer to the second surface than the first portion is. The first electrode is provided on the at least one side surface. The second electrode is provided on the at least one side surface.

### BACKGROUND

### 1. Technical Field

The present disclosure relates to an optical sensor.

### 2. Description of the Related Art

Photoelectric conversion elements that convert light energy into electrical energy are widely used as solar cells or optical sensors. Many photoelectric conversion elements made from inorganic materials such as silicon single crystals and silicon polycrystals have been developed.

For example, as disclosed in JANA ZAUMSEIL et al., “Electron and Ambipolar Transport in Organic Field-Effect Transistors”, Chemical Reviews, American Chemical Society, 2007, vol. 107, No. 4, pp. 1296-1323, vigorous studies have recently been conducted on organic semiconductor materials having physical properties and functions that conventional inorganic materials do not have. Organic photoelectric conversion elements, i.e. photoelectric conversion elements made from organic semiconductor materials, have been developed too.

As described in Japanese Unexamined Patent Application Publication No. 2018-190964, an organic photoelectric conversion element generally includes a pair of electrodes formed parallel to a substrate and an organic photoelectric conversion film disposed between the two electrodes. As described in Japanese Unexamined Patent Application Publication No. 2006-66535, there has been proposed a structure including a pair of electrodes formed perpendicularly to a substrate and an organic semiconductor disposed between the two electrodes.

### SUMMARY

In one general aspect, the techniques disclosed here feature an optical sensor including a substrate, a photoelectric conversion layer supported by the substrate, a first electrode, and a second electrode. The photoelectric conversion layer has a first surface facing the substrate, a second surface located opposite the first surface, and at least one side surface connecting the first surface with the second surface. The first electrode includes a first portion and a second portion separated from the first portion. The second portion is closer to the second surface than the first portion is. The first electrode is provided on the at least one side surface. The second electrode is provided on the at least one side surface.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic cross-sectional view of an optical sensor according to an embodiment of the present disclosure;

FIG. 1B is a top view of the optical sensor shown in FIG. 1A;

FIG. 1C is a side view of the optical sensor shown in FIG. 1A;

FIG. 1D is a top view of the optical sensor with a photoelectric conversion layer having the shape of a circular column;

FIG. 1E is a cross-sectional view of the optical sensor with the photoelectric conversion layer having at least one carrier blocking layer;

FIG. 2 is a schematic cross-sectional view of an optical sensor according to Modification 1;

FIG. 3 is a schematic cross-sectional view of an optical sensor according to Modification 2;

FIG. 4 is a schematic cross-sectional view of an optical sensor according to Modification 3;

FIG. 5 is a schematic cross-sectional view of an optical sensor according to Modification 4;

FIG. 6 is a schematic cross-sectional view of an optical sensor according to Modification 5;

FIG. 7A is a schematic cross-sectional view of an optical sensor according to Modification 6;

FIG. 7B is a top view of the optical sensor shown in FIG. 7A;

FIG. 8A is a schematic cross-sectional view of an optical sensor according to Modification 7;

FIG. 8B is a top view of the optical sensor shown in FIG. 8A;

FIG. 8C is a top view of the optical sensor shown in FIG. 8A with a photoelectric conversion layer having the shape of a circular column;

FIG. 8D is a top view of the optical sensor shown in FIG. 8A with the photoelectric conversion layer having the shape of a circular column and a first electrode having the shape of a circular cylinder;

FIG. 9A is a schematic cross-sectional view of an optical sensor according to Modification 8;

FIG. 9B is a schematic cross-sectional view of the optical sensor according to Modification 8;

FIG. 10A is a top view of an optical sensor according to Modification 9;

FIG. 10B is a side view of the optical sensor shown in FIG. 10A;

FIG. 11A is a diagram showing a process for manufacturing an optical sensor of the present disclosure;

FIG. 11B is a diagram showing the process for manufacturing an optical sensor of the present disclosure;

FIG. 11C is a diagram showing the process for manufacturing an optical sensor of the present disclosure; and

FIG. 12 is a block diagram of an imaging apparatus according to a second embodiment of the present disclosure.

### DETAILED DESCRIPTIONS

### Brief Overview of Aspects of the Present Disclosure

According to a first aspect of the present disclosure, there is provided an optical sensor including:

a substrate;

a photoelectric conversion layer that has a first surface facing the substrate, a second surface located opposite the first surface, and at least one side surface connecting the first surface with the second surface, the photoelectric conversion layer being supported by the substrate;

a first electrode provided on the at least one side surface, the first electrode including a first portion and a second portion separated from the first portion, the second portion being closer to the second surface than the first portion is; and

a second electrode provided on the at least one side surface.

Such a configuration makes it possible to provide an optical sensor having a simple structure while being able to detect light of a plurality of wavelengths.

In a second aspect of the present disclosure, e.g. in the optical sensor according to the first aspect, an area of the first portion of the first electrode may be larger than an area of the second portion of the first electrode. Such a configuration makes it possible to increase the sensitivity of the optical sensor.

In a third aspect of the present disclosure, e.g. in the optical sensor according to the first or second aspect, the second electrode may include a first portion and a second portion separated from the first portion of the second electrode, the second portion of the second electrode being closer to the second surface than the first portion of the second electrode is. Such a configuration makes it possible to increase the sensitivity of the optical sensor.

In a fourth aspect of the present disclosure, e.g. in the optical sensor according to the third aspect, an area of the first portion of the second electrode may be larger than an area of the second portion of the second electrode. Such a configuration makes it possible to further increase the sensitivity of the optical sensor.

In a fifth aspect of the present disclosure, e.g. in the optical sensor according to any one of the first to fourth aspects, an angle formed by the at least one side surface and the first surface may be larger than 90 degrees. Such a configuration brings about improvement in the efficiency with which carriers are taken out from the electrodes.

In a sixth aspect of the present disclosure, e.g. in the optical sensor according to any one of the first to fifth aspects, the at least one side surface may include a third surface connecting the first surface with the second surface and a fourth surface connecting the first surface with the second surface, the fourth surface being different from the third surface, the first electrode may be provided on the third surface, and the second electrode may be provided on the fourth surface. Such a configuration makes it possible to generate an electric field of uniform intensity within the photoelectric conversion layer.

In a seventh aspect of the present disclosure, e.g. in the optical sensor according to the sixth aspect, an angle formed by the third surface and the first surface may be larger than 90 degrees. Such a configuration brings about improvement in the efficiency with which carriers are taken out from the electrodes.

In an eighth aspect of the present disclosure, e.g. in the optical sensor according to the sixth or seventh aspect, an angle formed by the fourth surface and the first surface may be larger than 90 degrees. Such a configuration brings about improvement in performance of the optical sensor.

In a ninth aspect of the present disclosure, e.g. in the optical sensor according to any one of the sixth to eighth aspects, the third surface and the fourth surface may be adjacent to each other.

In a tenth aspect of the present disclosure, e.g. in the optical sensor according to any one of the sixth to eighth aspects, the at least one side surface may further include a fifth surface and a sixth surface, the fifth surface may be located between the third surface and the fourth surface and connect the first surface with the second surface, and the sixth surface may be a surface different from the third surface, the fourth surface, and the fifth surface and connect the first surface with the second surface. Such a configuration makes it easy to dispose electrodes.

In an eleventh aspect of the present disclosure, e.g. in the optical sensor according to any one of the first to tenth aspects, the first electrode may further include a third portion separated from the second portion of the first electrode, the third portion of the first electrode being closer to the second surface than the second portion of the first electrode is, the second electrode may include a first portion, a second portion, and a third portion, the second portion of the second electrode being separated from the first portion of the second electrode and being closer to the second surface than the first portion of the second electrode is, the third portion of the second electrode being separated from the second portion of the second electrode and being closer to the second surface than the second portion of the second electrode is, and the second portion of the first electrode and the second portion of the second electrode may function as shield electrodes. The shield electrodes makes it possible to prevent mixture of data based on electric charge collected by the first portion of the first electrode and the first portion of the second electrode and data based on electric charge collected by the third portion of the first electrode and the third portion of the second electrode.

According to a twelfth aspect of the present disclosure, there is provided an optical sensor including:

a substrate;

a photoelectric conversion layer that has a first surface facing the substrate, a second surface located opposite the first surface, and a third surface connecting the first surface with the second surface, the photoelectric conversion layer being supported by the substrate;

a first electrode provided on the third surface, the first electrode including a first portion and a second portion separated from the first portion, the second portion being closer to the second surface than the first portion is; and

a second electrode located within the photoelectric conversion layer.

The twelfth aspect makes it possible to provide an optical sensor having a simple structure while being able to detect light of a plurality of wavelengths.

In a thirteenth aspect of the present disclosure, e.g. in the optical sensor according to any one of the first to twelfth aspects, the photoelectric conversion layer may contain an organic material.

In a fourteenth aspect of the present disclosure, e.g. in the optical sensor according to any one of the first to thirteenth aspects, at all depth positions along a direction from the first surface toward the second surface, the photoelectric conversion layer may have a hole-transporting ability and/or an electron-transporting ability.

In a fifteenth aspect of the present disclosure, e.g. in the optical sensor according to any one of the first to fourteenth aspects, the photoelectric conversion layer may have electrical conductivity over a range from the first surface to the second surface.

In a sixteenth aspect of the present disclosure, e.g. in the optical sensor according to any one of the first to fifteenth aspects, the photoelectric conversion layer may convert light having a first wavelength into a first electric charge and converts light having a second wavelength into a second electric charge, the first portion of the first electrode may collect the first electric charge more than the second electric charge, and the second portion of the first electrode may collect the second electric charge more than the first electric charge.

In a seventeenth aspect of the present disclosure, e.g. in the optical sensor according to sixteenth aspect, an absorption coefficient of the photoelectric conversion layer at the second wavelength may be higher than an absorption coefficient of the photoelectric conversion layer at the first wavelength.

The following describes embodiments of the present disclosure with reference to the drawings. The present disclosure is not limited to the following embodiments.

### First Embodiment

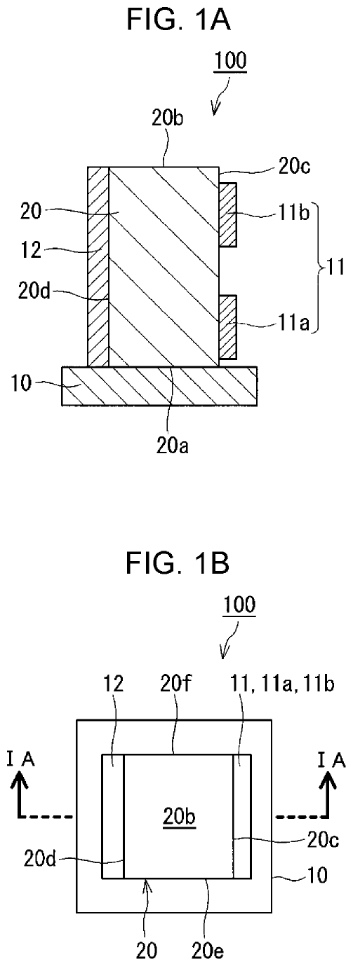

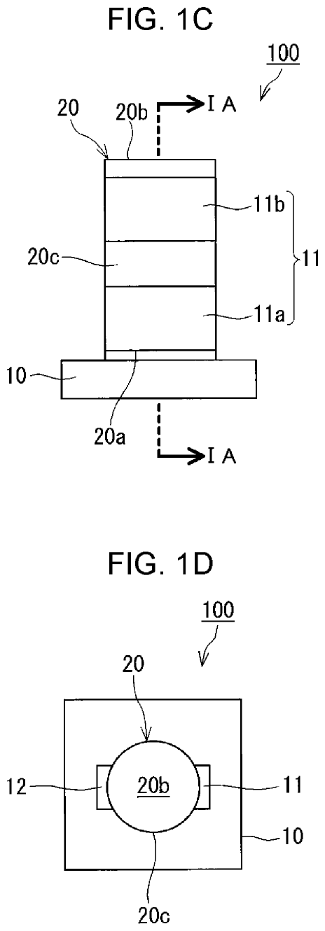

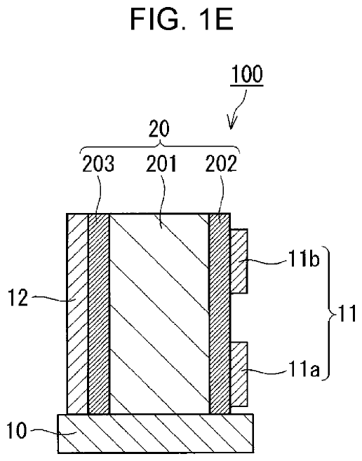

FIG. 1A shows a schematic cross section of an optical sensor 100 according to an embodiment of the present disclosure. FIG. 1B is a top view of the optical sensor 100 shown in FIG. 1A. FIG. 1C is a side view of the optical sensor 100 shown in FIG. 1A. The optical sensor 100 includes a substrate 10, a first electrode 11, a second electrode 12, and a photoelectric conversion layer 20. The photoelectric conversion layer 20 is supported by the substrate 10. The first electrode 11 and the second electrode 12 are attached to the photoelectric conversion layer 20.

The substrate 10 may be a circuit board including various types of electronic circuit. The substrate 10 is a semiconductor substrate and is constituted, for example, by a silicon substrate. The substrate 10 may be a plastic substrate or a glass substrate. It is not essential that the substrate 10 include electronic circuits. Electronic circuits may be provided on the substrate 10. For the prevention of leakage of electric charge from the photoelectric conversion layer 20, the substrate 10 may have a surface made from an insulating material.

The photoelectric conversion layer 20 has a first surface 20a, a second surface 20b, and at least one side surface. The first surface 20a is a lower surface of the photoelectric conversion layer 20 and faces the substrate 10. In the present embodiment, the first surface 20a is in contact with the substrate 10. The second surface 20b is an upper surface of the photoelectric conversion layer 20 and is located opposite the first surface 20a. The second surface 20b may be a light receiving surface of the photoelectric conversion layer 20. Another member such as a color filter and a microlens may be disposed on or above the second surface 20b.

The first electrode 11 is provided on the at least one side surface of the photoelectric conversion layer 20. The first electrode 11 includes a first portion 11a and a second portion 11b. The second portion 11b is a portion located above the first portion 11a. That is, the first portion 11a is located close to the substrate 10. The second portion 11b is located away from the substrate 10. That is, the second portion 11b is closer to the second surface 20b than the first portion 11a. In a depth direction parallel with the depth of the photoelectric conversion layer 20, the first portion 11a and the second portion 11b are separated from each other. The first portion 11a and the second portion 11b are each connected to a readout circuit (not illustrated). In the depth direction parallel with the depth of the photoelectric conversion layer 20, the first electrode 11 may be divided into three or more portions. The depth direction parallel with the depth of the photoelectric conversion layer 20 may be a direction parallel to a normal to the substrate 10.

The second electrode 12 is provided on the at least one side surface of the photoelectric conversion layer 20.

When light is shone on the second surface 20b of the photoelectric conversion layer 20, light having a wavelength with a higher absorption coefficient is absorbed into the photoelectric conversion layer 20 first, then light having a wavelength with a lower absorption coefficient. Light having a wavelength with a lower absorption coefficient remains farther in the depth direction parallel with the depth of the photoelectric conversion layer 20. Since the first electrode 11 is separated into the plurality of portions 11a and 11b along the depth direction parallel with the depth of the photoelectric conversion layer 20, the light thus shone can be separated according to location in the depth direction, i.e. according to wavelength.

When light is absorbed into the photoelectric conversion layer 20, electron-hole pairs are generated by photoelectric conversion. Carries, namely electrons and holes, migrate toward either the first electrode 11 or the second electrode 12. Carriers having arrived at the first electrode 11 are converted by the readout circuit into color data. For example, data regarding light having a wavelength with a high absorption coefficient is generated on the basis of carriers read out from the second portion 11b located close to the second surface 20b serving as a light receiving surface. Data regarding light having a wavelength with a low absorption coefficient is generated on the basis of carriers read out from the first portion 11a located away from the second surface 20b serving as a light receiving surface.

For example, the absorption coefficient of the photoelectric conversion layer 20 for near infrared radiation is high and the absorption coefficient of the photoelectric conversion layer 20 for visible radiation is low, data regarding the near infrared radiation is generated on the basis of carriers read out from the second portion 11b of the first electrode 11. Data regarding the visible radiation is generated on the basis of carriers read out from the first portion 11a of the first electrode 11. The visible radiation herein falls within a wavelength range of 400 nm to 780 nm. The near infrared radiation herein falls within a wavelength range of 780 nm to 2000 nm.

The photoelectric conversion layer 20 is not separated in the depth direction, and no insulating layer is present on a path from the first surface 20a to the second surface 20b. Since no insulating layer is provided, the photoelectric conversion layer 20 is free from thermal or mechanical damage expected to occur when an insulating layer is formed.

In this way, the optical sensor 100 of the present embodiment has a simple structure while being able to detect light of a plurality of wavelengths.

The second electrode 12 is disposed in a position different from the position in which the first electrode 11 is provided. The term “position different from the position in which the first electrode 11 is provided” means a position that, in a plan view of the optical sensor 100, does not overlap the position in which the first electrode 11 is provided. In the present embodiment, the second electrode 12 faces the first electrode 11 across the photoelectric conversion layer 20. In other words, the photoelectric conversion layer 20 is disposed between the first electrode 11 and the second electrode 12.

The first electrode 11 and the second electrode 12 are constituted by an electrical conducting material. The electrical conducting material may be a metal such as copper or aluminum, an electrical conducting nitride such as TiN, an electrical conducting metal oxide such as SnO₂ or ITO (indium tin oxide), electrical conducting polysilicon, or an electrical conducting polymer.

The first and second portions 11a and 11b of the first electrode 11 both have the shape of a rectangle in plan view. The second electrode 12 too has the shape of a rectangle in plan view. Note, however, that the shapes of the first portion 11a of the first electrode 11, the second portion 11b of the first electrode 11, and the second electrode 12 are not limited to particular shapes. The area of the first portion 11a may be equal to or different from the area of the second portion 11b.

The area of the second electrode 12 is larger than that of the first portion 11a of the first electrode 11 and larger than that of the second portion 11b of the first electrode 11. The second electrode 12 is not separated in the direction parallel to the depth of the photoelectric conversion layer 20. By applying a voltage to the second electrode 12, an uniform electric field can be generated within the photoelectric conversion layer 20.

The first electrode 11 and the second electrode 12 are in contact with both p-type and n-type semiconductors constituting the photoelectric conversion layer 20. The first electrode 11, the second electrode 12, and the photoelectric conversion layer 20 are made from materials that may be selected so that only holes flow into one electrode and only electrons flow into the other electrode. Specifically, a work function of the material from which the first electrode 11 is made, a work function of the material from which the second electrode 12 is made, and HOMO and LUMO energy levels of an organic semiconductor from which the photoelectric conversion layer 20 is made are taken into account. A bias voltage is applied between the first electrode 11 and the second electrode 12 through a wire (not illustrated) so that carriers for use in readout can be taken out by the first or second portion 11a or 11b of the first electrode 11.

The at least one side surface of the photoelectric conversion layer 20 is a surface connecting the first surface 20a with the second surface 20b. The at least one side surface extends from the first surface 20a to the second surface 20b. In the present embodiment, the at least one side surface includes a third surface 20c and a fourth surface 20d. The third surface 20c and the fourth surface 20d are both surfaces connecting the first surface 20a with the second surface 20b. Note, however, that the fourth surface 20d is a surface different from the third surface 20c. In the present embodiment, the third surface 20c and the fourth surface 20d are for example surfaces facing each other and surfaces parallel to each other. In the present embodiment, the first electrode 11 is provided on the third surface 20c. The second electrode 12 is provided on the fourth surface 20d. Such a configuration makes it possible to generate an electric field of uniform intensity within the photoelectric conversion layer 20.

In a plan view of the optical sensor 100, the shape of the photoelectric conversion layer 20 may be a regular square or a rectangle having long sides and short sides. For example, in a case where the optical sensor 100 is used as a part of an imaging element, a display that shows a picture acquired by the imaging element is rectangular. Therefore, there is a merit in forming the photoelectric conversion layer 20 in the shape of a rectangle and designing the imaging element so that the area of the photoelectric conversion layer 20 can be maximally ensured within a pixel.

In the present embodiment, the at least one side surface of the photoelectric conversion layer 20 further includes a fifth surface 20e and a sixth surface 20f. The fifth surface 20e is located between the third surface 20c and the fourth surface 20d and connects the first surface 20a with the second surface 20b. The sixth surface 20f is a surface different from the third surface 20c, the fourth surface 20d, and the fifth surface 20e and connects the first surface 20a with the second surface 20b. The third surface 20c and the fourth surface 20d face each other. The fifth surface 20e and the sixth surface 20f face each other. Each of these surfaces is a flat surface. The photoelectric conversion layer 20 has the shape of a polygonal column, in particular a quadrangular prism. No electrodes are provided on the fifth surface 20e or the sixth surface 20f. When the photoelectric conversion layer 20 has four or more side surfaces, it is easy to dispose electrodes. Further, as will be mentioned later, it becomes possible to dispose electrodes separately on each of the four surface.

The photoelectric conversion layer 20 is constituted by a photoelectric conversion material. The photoelectric conversion material may be an organic material. The photoelectric conversion layer 20 has electrical conductivity between the first surface 20a and the second surface 20b. Photoelectric conversion may be carried out at all depth positions from the first surface 20a to the second surface 20b.

The photoelectric conversion layer 20 contains at least one type of p-type organic semiconductor and at least one type of n-type organic semiconductor. An appropriate combination of a p-type organic semiconductor and an n-type organic semiconductor may be used so that the photoelectric conversion layer 20 exhibits different absorption coefficients according to wavelengths of light. The optical sensor 100 may have sensitivity to any wavelength range of light.

The p-type organic semiconductor is a donor organic semiconductor, is typified by an organic compound having a hole-transporting ability, and is an organic compound having such a property as to easily donate electrons. In particular, the p-type organic semiconductor is an organic compound that has a lower ionization potential when two types of organic compound are brought into contact with each other. Accordingly, the donor organic semiconductor is not limited to a particular organic compound, provided it is an organic compound having an electron-donating ability. Examples of the p-type organic semiconductor include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyallylene compound, a condensed aromatic carbon ring compound, and a metal complex having a nitrogen-containing hetero ring compound as a ligand. Examples of the condensed aromatic carbon ring compound include a naphthalene derivative, an anthracene derivative, a phenanthrene derivative, a tetracene derivative, a pyrene derivative, a perylene derivative, and a fluoranthene derivative. One type or two or more types selected from among these compounds may be used. Note, however, that the p-type organic semiconductor is not limited to these compounds. As noted above, an organic compound having a lower ionization potential than an organic compound used as an acceptor organic compound may be used as a donor organic semiconductor.

The n-type organic semiconductor is an acceptor organic semiconductor, is typified by an organic compound having an electron-transporting ability, and is an organic compound having such a property as to easily accept electrons. In particular, the n-type organic semiconductor is an organic compound that has a higher electron affinity when two types of organic compound are brought into contact with each other. Accordingly, the acceptor organic semiconductor is not limited to a particular organic compound, provided it is an organic compound having an electron-accepting ability. Examples of the n-type organic semiconductor include fullerene, a fullerene derivative, a condensed aromatic carbon ring compound, a hetero ring compound, a polyallylene compound, a fluorene compound, a cyclopentadiene compound, a silyl compound, and a metal complex having a nitrogen-containing hetero ring compound as a ligand. Examples of the condensed aromatic carbon ring compound include a naphthalene derivative, an anthracene derivative, a phenanthrene derivative, a tetracene derivative, a pyrene derivative, a perylene derivative, and a fluoranthene derivative. The hetero ring compound may be a 5-membered ring to 7-membered ring compound containing at least one of a nitrogen atom, an oxygen atom, or a sulfur atom. Examples of the hetero ring compound include pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazopyridine, dibenzazepine, and tribenzazepine. One type or two or more types selected from among these compounds may be used. Note, however, that the n-type organic semiconductor is not limited to these compounds. As noted above, an organic compound having a higher electron affinity than an organic compound used as a donor organic compound may be used as an acceptor organic semiconductor.

The photoelectric conversion layer 20 may have a bulk heterojunction structure including a p-type semiconductor and an n-type semiconductor. A bulk heterojunction structure brings about improvement in photoelectric conversion efficiency by covering the shortcoming of an organic semiconductor having a short carrier diffusion length.

In a case where the photoelectric conversion layer 20 has a bulk heterojunction structure, the rectifiability of holes and electrons is increased by sandwiching the bulk heterojunction structure between paired carrier blocking layers. In particular, the injection of carries from the electrodes is suppressed. This brings about a reduction of losses produced, for example, by the recombination of holes and electrons near the electrodes, making it possible to attain higher photoelectric conversion efficiency. Furthermore, with a reduction of a dark current produced by the injection of carriers from the electrodes, the S/N ratio of the sensor can be increased. It is not essential that the pair of carrier blocking layers be provided. Only one carrier blocking layer selected from among an electron blocking layer and a hole blocking layer may be provided.

In a case where the photoelectric conversion layer 20 has a bulk heterojunction structure, the composition of the material in the photoelectric conversion layer 20 may be uniform throughout the photoelectric conversion layer 20, or may vary from place to place. The former makes it easy to fabricate the photoelectric conversion layer 20. The latter makes it possible to increase the capacity to separate light according to wavelength. The composition may continuously or gradually vary in the depth direction. In one example, the photoelectric conversion layer 20 may be configured such that the concentration of a material with a high absorption coefficient for near infrared radiation is high in a portion near the second surface 20b and low in a portion near the first surface 20a.

The photoelectric conversion layer 20 may have a planar heterojunction structure. A planar heterojunction structure is characterized in that the mobility of carriers hardly decreases and that the probability of recombination of holes and electrons is low, as the structure has separate carrier migration paths for holes and electrons. Therefore, a planar heterojunction structure makes it possible to take out carriers with high probability.

In a case where the photoelectric conversion layer 20 has a planar heterojunction structure, the rectifiability of holes and electrons is increased by sandwiching the planar heterojunction structure between paired carrier blocking layers. In particular, the injection of carries from the electrodes is suppressed. This brings about a reduction of losses produced, for example, by the recombination of holes and electrons near the electrodes, making it possible to attain higher photoelectric conversion efficiency. Furthermore, with a reduction of a dark current produced by the injection of carriers from the electrodes, the S/N ratio of the sensor can be increased. It is not essential that the pair of carrier blocking layers be provided. Only one carrier blocking layer selected from among an electron blocking layer and a hole blocking layer may be provided.

Photoelectric conversion efficiency is determined by factors such as carrier diffusion length, carrier mobility, and recombination probability. Therefore, an optimum structure is selected from among a bulk heterojunction structure and a planar heterojunction structure according to the photoelectric conversion material.

For the collection of charge corresponding to near infrared radiation, a planar heterojunction structure is suitable. A material having sensitivity to near infrared radiation, i.e. light of wavelengths longer than those of visible radiation, has a small bandgap. Therefore, using such a material tends to cause a dark current to be produced by thermal excitation. However, a planar heterojunction structure has a small area donor/acceptor interface and therefore reduces the probability of generation of electric charge, so that a dark current may be suppressed.

The term “planar heterojunction” herein means a junction having a planar donor/acceptor interface. The term “bulk heterojunction” means a junction formed by materials of different physical properties being randomly mixed without having a clear interface.

In each of the examples shown in FIGS. 1A to 1C, the photoelectric conversion layer 20 has the shape of a prism. Note, however, that the three-dimensional shape of the photoelectric conversion layer 20 is not limited to a particular shape. The shape of the photoelectric conversion layer 20 may be a prism, a circular column, an elliptical column, a truncated pyramid, or a truncated cone.

FIG. 1D is a top view of the optical sensor 100 with the photoelectric conversion layer 20 having the shape of a circular column. In the example shown in FIG. 1D, the photoelectric conversion layer 20 has only one circular cylindrical side surface defined as the third surface 20c. The first electrode 11 and the second electrode 12 are attached to the third surface 20c. In a direction along the circumference of the circular cylindrical third surface 20c, the first electrode 11 is placed 180 degrees opposite the second electrode 12.

FIG. 1E shows a cross-section of the optical sensor 100 with the photoelectric conversion layer 20 having carrier blocking layers 202 and 203. In the example shown in FIG. 1E, the photoelectric conversion layer 20 includes a photoelectric conversion portion 201, the carrier blocking layer 202, and the carrier blocking layer 203. The photoelectric conversion portion 201 is disposed between the carrier blocking layer 202 and the carrier blocking layer 203. The carrier blocking layer 202 is disposed between and is in contact with the first electrode 11 and the photoelectric conversion portion 201. The carrier blocking layer 203 is disposed between and is in contact with the second electrode 12 and the photoelectric conversion portion 201. One of the carrier blocking layers 202 and 203 is an electron blocking layer, and the other of the carrier blocking layers 202 and 203 is a hole blocking layer. For example, in a case where data is generated by reading out holes from the first electrode 11, the carrier blocking layer 202 is an electron blocking layer and the carrier blocking layer 203 is a hole blocking layer.

The electron blocking layer is provided to reduce a dark current produced by the injection of electrons from the electrode, and inhibits the injection of electrons from the electrode into the photoelectric conversion portion 201. The electron blocking layer can be made from the aforementioned p-type semiconductor or organic compound having a hole-transporting ability. The electron blocking layer has a higher LUMO energy level than the p-type semiconductor of the photoelectric conversion portion 201. In other words, the photoelectric conversion portion 201 has a lower LUMO energy level than the electron blocking layer near the interface between the photoelectric conversion portion 201 and the electron blocking layer. The thickness of the electron blocking layer is not limited to a particular value, as it depends on the configuration of the photoelectric conversion portion 201. For example, the thickness of the electron blocking layer falls within a range of 2 nm to 100 nm.

The hole blocking layer is provided to reduce a dark current produced by the injection of holes from the electrode, and inhibits the injection of holes from the electrode into the photoelectric conversion portion 201. The hole blocking layer may be made from an organic substance, an inorganic substance, or an organic metal compound. Examples of the organic substance include copper phthalocyanine, 3,4,9,10-perylene tetracarboxylic acid dianhydride (PTCDA), an acetylacetonate complex, bathocuproine (BCP), and tris(8-quinolinolato)aluminum (Alq3). Examples of the inorganic substance include MgAg and MgO. One type or two or more types selected from among these materials may be used. The thickness of the hole blocking layer is not limited to a particular value, as it depends on the configuration of the photoelectric conversion portion 201. For example, the thickness of the hole blocking layer falls within a range of 2 nm to 50 nm. The hole blocking layer can be made from the aforementioned n-type semiconductor or organic compound having an electron-transporting ability.

The following describes optical sensors according to modifications. Elements common to the optical sensor 100 described earlier and the optical sensors according to the modifications are given the same reference signs, and a description of those elements may be omitted. A description of each modification may be applied to that of the other modification unless a technical contradiction arises. Unless a technical contradiction arises, each optical sensor may be combined with the other optical sensor.

### Modification 1

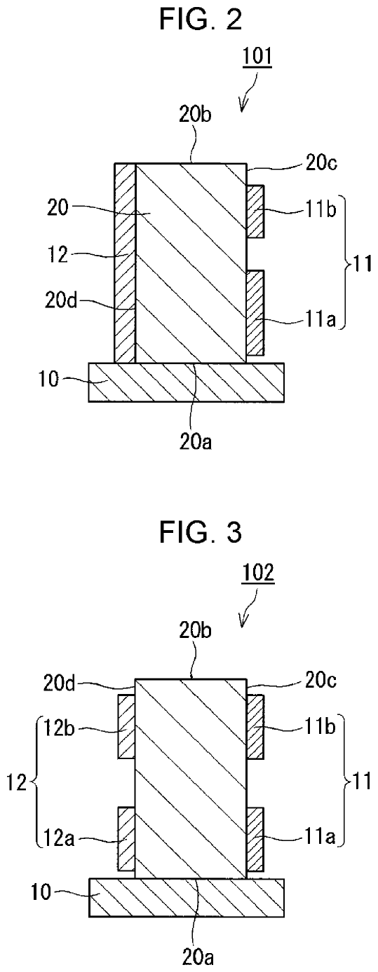

FIG. 2 shows a schematic cross-section of an optical sensor 101 according to Modification 1. In the optical sensor 101, the area of the first portion 11a of the first electrode 11 is larger than the area of the second portion 11b of the first electrode 11. The size of the first portion 11a in the depth direction exceeds the size of the second portion 11b in the depth direction. That is, the area of the electrode increases away from the second surface 20b serving as a light receiving surface. The area of the electrode may be the area of the interface between the electrode and the photoelectric conversion layer 20.

The amount of light that is received by the photoelectric conversion layer 20 decreases away from the second surface 20b. Since the area of the electrode increases away from the second surface 20b, a sufficient amount of electric charge can be collected, even with a decrease in the amount of light that is received. That is, the sensitivity of the optical sensor 101 can be increased.

The ratio of the area of the second portion 11b of the first electrode 11 to the area of the first portion 11a of the first electrode 11 is not limited to a particular value. The ratio can be determined according to the characteristics of the photoelectric conversion layer 20.

Even if the first electrode 11 is separated into three or more portions, the configuration of the present modification may be adopted. That is, the first electrode 11 can be constituted by a plurality of separated portions so that the area of a separated portion that is farther away from the second surface 20b is larger than the area of a separated portion that is closer to the second surface 20b.

### Modification 2

FIG. 3 shows a schematic cross-section of an optical sensor 102 according to Modification 2. In the optical sensor 102, the second electrode 12, as well as the first electrode 11, is divided into a plurality of portions in the depth direction parallel with the depth of the photoelectric conversion layer 20. Specifically, the second electrode 12 includes a first portion 12a and a section portion 12b. The second portion 12b is a portion located above the first portion 12a. That is, the first portion 12a is located close to the substrate 10. The second portion 12b is located away from the substrate 10. That is, the second portion 12b is closer to the second surface 20b than the first portion 12a. In the depth direction parallel with the depth of the photoelectric conversion layer 20, the first portion 12a and the second portion 12b are separated from each other. The first portion 12a and the second portion 12b are each connected to a voltage control circuit (not illustrated). In the depth direction parallel with the depth of the photoelectric conversion layer 20, the second electrode 12 may be divided into three or more portions.

In the present modification, the number of portions that constitute the first electrode 11 is equal to the number of portions that constitute the second electrode 12. The first portion 11a of the first electrode 11 and the first portion 12a of the second electrode 12 face each other. The second portion 11b of the first electrode 11 and the second portion 12b of the second electrode 12 face each other. The magnitude of a bias voltage applied between the first portion 11a of the first electrode 11 and the first portion 12a of the second electrode 12 may be identical to or different from the magnitude of a bias voltage applied between the second portion 11b of the first electrode 11 and the second portion 12b of the second electrode 12. For example, when the magnitude of a bias voltage that is applied farther away from the second surface 20b is greater than the magnitude of a bias voltage that is applied closer to the second surface 20b, the amount of electric charge that is taken out can be increased, even with a decrease in the amount of light that is received. That is, the sensitivity of the optical sensor 101 can be increased.

The number of portions that constitute the first electrode 11 may be different from the number of portions that constitute the second electrode 12.

### Modification 3

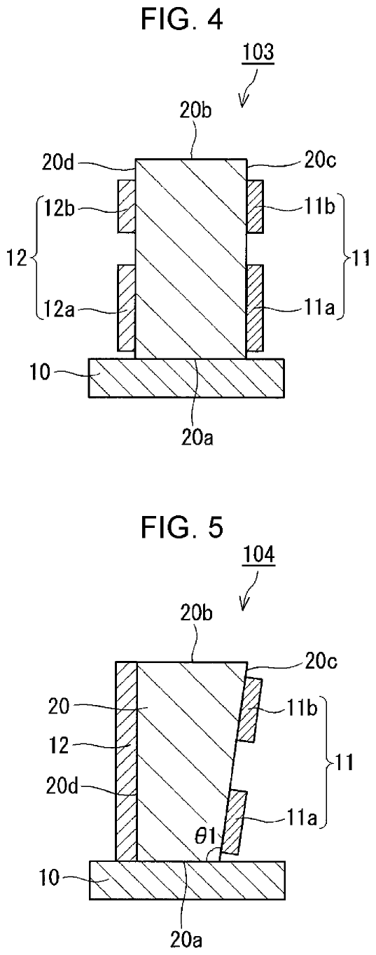

FIG. 4 shows a schematic cross-section of an optical sensor 103 according to Modification 3. The optical sensor 103 is a combination of the optical sensor 101 (FIG. 2) of Modification 1 and the optical sensor 102 (FIG. 3) of Modification 2. That is, the area of the first portion 11a of the first electrode 11 is larger than the area of the second portion 11b of the first electrode 11, and the area of the first portion 12a of the second electrode 12 is larger than the area of the second portion 12b of the second electrode 12. The optical sensor 103 of Modification 3 brings about multiple effects of Modifications 1 and 2. That is, the sensitivity of the optical sensor 103 can be further increased.

### Modification 4

FIG. 5 shows a schematic cross-section of an optical sensor 104 according to Modification 4. In the present modification, an angle θ1 formed by the at least one side surface of the photoelectric conversion layer 20 and the first surface 20a of the photoelectric conversion layer 20 is larger than 90 degrees. In other words, the at least one side surface of the photoelectric conversion layer 20 is inclined with respect to the depth direction so that the distance (i.e. the shortest distance) between the first electrode 11 and the second electrode 12 decreases from the second surface 20b toward the first surface 20a. The at least one side surface may be a surface on which an electrode is provided. A surface on which no electrode is provided may be inclined with respect to the first surface 20a. In the present modification, the angle θ1 formed by the third surface 20c and the first surface 20a is larger than 90 degrees. The third surface 20c is inclined with respect to the depth direction. The fourth surface 20d is parallel to the depth direction. Instead of or in addition to the third surface 20c, another side surface, e.g. the fourth surface 20d, may be inclined. The angle θ1 is an interior angle of the photoelectric conversion layer 20. The angle θ1 is for example larger than 90 degrees and smaller than or equal to 120 degrees. The angle θ1 may be identified in a given cross-section of the optical sensor 104 in a direction parallel with the depth direction.

The present modification, according to which the interelectrode distance decreases away from the second surface 20b of the photoelectric conversion layer 20, brings about improvement in the efficiency with which carriers are taken out. Further, in the process of forming the photoelectric conversion layer 20, the photoelectric conversion material is easily brought into close contact with the third surface 20c, which is a surface on which the first electrode 11 is formed. In other words, the photoelectric conversion material is easily brought into close contact with a surface of the first electrode 11. This results in improvement in performance of the optical sensor 104.

### Modification 5

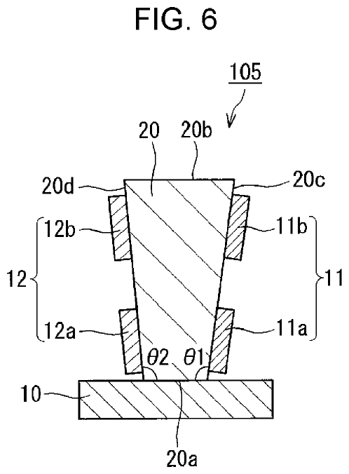

FIG. 6 shows a schematic cross-section of an optical sensor 105 according to Modification 5. The optical sensor 105 is a combination of the optical sensor 102 (FIG. 3) of Modification 2 and the optical sensor 104 (FIG. 5) of Modification 4. That is, the second electrode 12, as well as the first electrode 11, includes a first portion 12a and a second portion 12b that are separated from each other in the depth direction. Further, an angle formed by the at least one side surface of the photoelectric conversion layer 20 and the first surface 20a of the photoelectric conversion layer 20 is larger than 90 degrees. In particular, an angle θ1 formed by the third surface 20c and the first surface 20a is larger than 90 degrees, and an angle θ2 formed by the fourth surface 20d and the first surface 20a is larger than 90 degrees. The third surface 20c, on which the first electrode 11 is provided, and the fourth surface 20d, on which the second electrode 12 is provided, are inclined with respect to the depth direction so that the distance between the first electrode 11 and the second electrode 12 decreases from the second surface 20b toward the first surface 20a. In the present modification too, the interelectrode distance decreases away from the second surface 20b of the photoelectric conversion layer 20. This brings about improvement in the efficiency with which carriers are taken out. Further, in the process of forming the photoelectric conversion layer 20, the photoelectric conversion material is easily brought into close contact with the third surface 20c, which is a surface on which the first electrode 11 is formed, and the fourth surface 20d, which is a surface on which the second electrode 12 is formed. In other words, the photoelectric conversion material is easily brought into close contact with a surface of the first electrode 11 and a surface of the second electrode 12. This results in improvement in performance of the optical sensor 105.

The angle θ2 may be equal to or different from the angle θ1. The angle θ2 too is an interior angle of the photoelectric conversion layer 20. The angle θ2 is for example larger than 90 degrees and smaller than or equal to 120 degrees.

### Modification 6

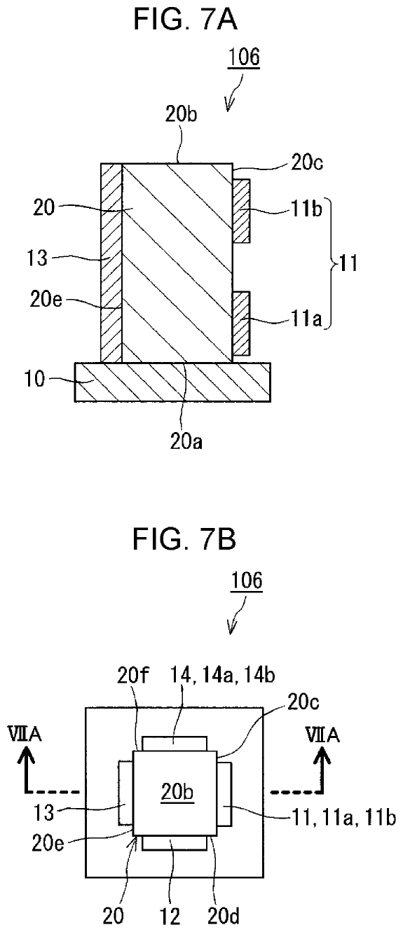

FIG. 7A shows a schematic cross-section of an optical sensor 106 according to Modification 6. FIG. 7B is a top view of the optical sensor 106 shown in FIG. 7A. According to the present modification, the third surface 20c, on which the first electrode 11 is provided, and the fourth surface 20d, on which the second electrode 12 is provided, are adjacent to each other.

The at least one side surface of the photoelectric conversion layer 20 further includes a fifth surface 20e and a sixth surface 20f. On the fifth surface 20e, a third electrode 13 is provided. On the sixth surface 20f, a fourth electrode 14 is provided. The fourth electrode 14 includes a first portion 14a and a second portion 14b. The second portion 14b is a portion located above the first portion 14a. That is, the first portion 14a is located close to the substrate 10. The second portion 14b is located away from the substrate 10. In the depth direction parallel with the depth of the photoelectric conversion layer 20, the first portion 14a and the second portion 14b are separated from each other. The first portion 14a and the second portion 14b are each connected to a readout circuit (not illustrated). The fifth surface 20e and the sixth surface 20f are adjacent to each other. The fifth surface 20e faces the third surface 20c. The sixth surface 20f faces the fourth surface 20d.

In the present modification, there are two pairs of electrodes facing each other across the photoelectric conversion layer 20. The first electrode 11 and the third electrode 13 constitute a pair of electrodes, and the second electrode 12 and the fourth electrode 14 constitute a pair of electrodes. Carriers are read out from the first electrode 11 and the fourth electrode 14. The magnitude of a bias voltage to be applied between the first electrode 11 and the third electrode 13 may be identical to or different from the magnitude of a bias voltage to be applied between the second electrode 12 and the fourth electrode 14. According to the present modification, electrodes of different voltages are adjacent to each other. The application of voltages to all side surfaces of the photoelectric conversion layer 20 makes it possible to reduce residual charge.

As described with reference to FIG. 3, the second electrode 12 may be constituted by a plurality of separated portions, e.g. a first portion and a second portion. The third electrode 13 may be constituted by a plurality of separated portions, e.g. a first portion and a second portion.

### Modification 7

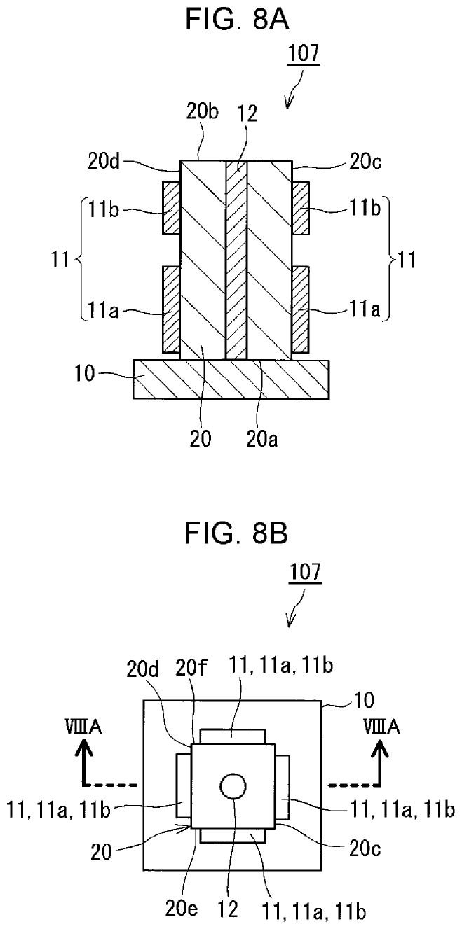

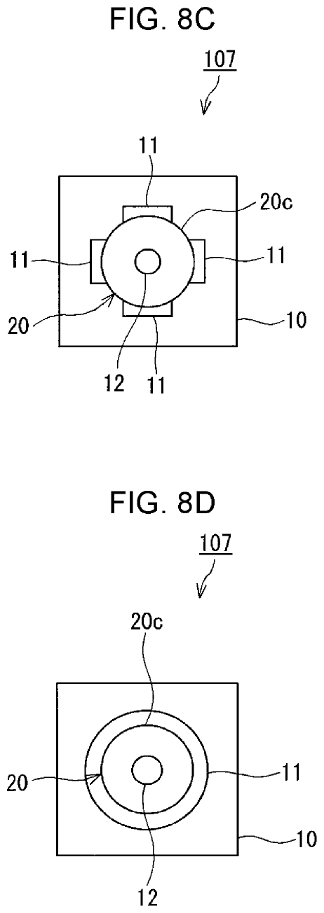

FIG. 8A shows a schematic cross-section of an optical sensor 107 according to Modification 7. FIG. 8B is a top view of the optical sensor 107 shown in FIG. 8A. In the optical sensor 107, the first electrode 11 is provided on the third surface 20c of the photoelectric conversion layer 20. The second electrode 12 is located within the photoelectric conversion layer 20. In particular, the optical sensor 107 includes a plurality of the first electrodes 11. The first electrodes 11 are disposed on the third, fourth, fifth, and sixth surfaces 20c, 20d, 20e, and 20f, respectively, of the photoelectric conversion layer 20. Each of the plurality of first electrodes 11 includes a first portion 11 a and a second portion 11b. The second electrode 12 is located in a central part of the photoelectric conversion layer 20 and extends from the first surface 20a to the second surface 20b. The second electrode 12 has, for example, a columnar shape. The second electrode 12 is surrounded by the plurality of first electrodes 11 across the photoelectric conversion layer 20. Disposition of electrodes within the photoelectric conversion layer 20 may shorten the distance covered by carriers while preventing a significant decrease in the amount of space in which photoelectric conversion is carried out. Increased electric field intensity between the first electrode 11 and the second electrode 12 brings about improvement in photoelectric conversion efficiency.

FIG. 8C is a top view of the optical sensor 107 with a photoelectric conversion layer 20 having the shape of a circular column. When the photoelectric conversion layer 20 has the shape of a circular column, the photoelectric conversion layer 20 has the third surface 20c as the sole side surface. The third surface 20c has the shape of a circular cylinder. The plurality of first electrodes 11 are placed at equal angular intervals on the third surface 20c. In the present modification, four first electrodes 11 are placed at equal angular intervals of 90 degrees in the direction along the circumference of the photoelectric conversion layer 20. The second electrode 12 is disposed in the central part of the photoelectric conversion layer 20. The second electrode 12 may be disposed concentrically with the photoelectric conversion layer 20. The example shown in FIG. 8C not only makes it possible to expect improvement in photoelectric conversion efficiency but also makes it possible to reduce residual charge, as the photoelectric conversion layer 20 has no corners. This results in making it easy to give the optical sensor 107 such a characteristic as to cause less image retention.

FIG. 8D is a top view of the optical sensor 107 with the photoelectric conversion layer 20 having the shape of a circular column and a first electrode 11 having the shape of a circular cylinder. The photoelectric conversion layer 20 has the third surface 20c as the sole side surface. The third surface 20c has the shape of a circular cylinder. On the third surface 20c, the first electrode 11 is provided. The first electrode 11 surrounds the photoelectric conversion layer 20 360 degrees. The second electrode 12 is disposed in the central part of the photoelectric conversion layer 20. The example shown in FIG. 8D too brings about the same effects as those of the examples shown in FIGS. 8B and 8C. Furthermore, the second electrode 12 is surrounded 360 degrees by the first electrode 11. This reduces the amount of space in which the electric field intensity partially weakens, making it possible to further reduce residual charge.

In each of the examples shown in FIGS. 8C and 8D, the first electrode 11 has a first portion 11a and a second portion 11b, although they do not appear in FIGS. 8C and 8D.

### Modification 8

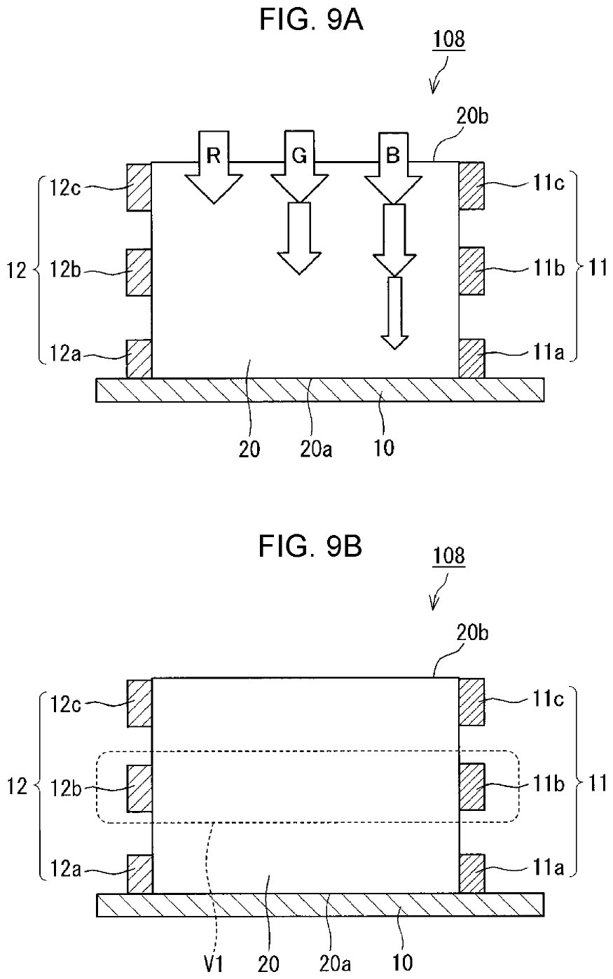

FIGS. 9A and 9B show schematic cross-sections of the optical sensor 108 according to Modification 8. An example of use of the optical sensor 108 shown in FIG. 9A is different from an example of use of the optical sensor 108 shown in FIG. 9B. The optical sensor 108 is equivalent to an example of improvement in the optical sensor 102 described with reference to FIG. 3. For convenience, the distance between the first electrode 11 and the second electrode 12 is drawn with exaggeration.

The optical sensor 108 includes a first electrode 11 and a second electrode 12 that are provided on at least one side surface of the photoelectric conversion layer 20. The first electrode 11 includes a first portion 11a, a second portion 11b, and a third portion 11c. In the depth direction parallel with the depth of the photoelectric conversion layer 20, the first portion 11a, the second portion 11b, and the third portion 11c are separated from one another. The second electrode 12 includes a first portion 12a, a second portion 12b, and a third portion 12c. In the depth direction parallel with the depth of the photoelectric conversion layer 20, the first portion 12a, the second portion 12b, and the third portion 12c are separated from one another.

In FIG. 9A, the arrow R represents red light. The arrow G represents green light. The arrow B represents blue light. The photoelectric conversion layer 20 is constituted by a photoelectric conversion material having sensitivity to visible radiation. The photoelectric conversion layer 20 is configured, for example, such that the red light is mainly absorbed at a depth position in which the third portions 11c and 12c of the electrodes are present, the green light is mainly absorbed at a depth position in which the second portions 11b and 12b of the electrodes are present, and the blue light is mainly absorbed at a depth position in which the first portions 11a and 12a of the electrodes are present. With variations in the composition of the photoelectric conversion layer 20 in the depth direction, the photoelectric conversion layer 20 is easily given such a characteristic. The variations in the composition may be achieved by a bulk heterojunction structure, or may be achieved by a planar heterojunction structure.

A predetermined bias voltage is applied between the third portion 11c of the first electrode 11 and the third portion 12c of the second electrode 12. Charge generated primarily from the red light is collected by the third portion 11c of the first electrode 11 and the third portion 12c of the second electrode 12. A predetermined bias voltage is applied between the second portion 11b of the first electrode 11 and the second portion 12b of the second electrode 12. Charge generated primarily from the green light is collected by the second portion 11b of the first electrode 11 and the second portion 12b of the second electrode 12. A predetermined bias voltage is applied between the first portion 11a of the first electrode 11 and the first portion 12a of the second electrode 12. Charge generated primarily from the blue light is collected by the first portion 11a of the first electrode 11 and the first portion 12a of the second electrode 12. Color data is generated on the basis of the charge collected by the electrodes. A matrix arrangement of a plurality of the optical sensors 108 makes it possible to, without using a color filter, form a full-color image on the basis of data obtained from the plurality of optical sensors 108.

In FIG. 9B, the dashed line portion V1 represents a shielded region. The photoelectric conversion layer 20 has, for example, sensitivity to visible radiation and near infrared radiation. A predetermined bias voltage is applied between the third portion 11c of the first electrode 11 and the third portion 12c of the second electrode 12. For example, charge generated primarily from near infrared radiation is collected by the third portion 11c of the first electrode 11 and the third portion 12c of the second electrode 12. On the basis of the charge thus collected, data regarding the near infrared radiation is generated. A predetermined bias voltage is applied between the first portion 11a of the first electrode 11 and the first portion 12a of the second electrode 12. For example, charge generated primarily from visible radiation is collected by the first portion 11a of the first electrode 11 and the first portion 12a of the second electrode 12. On the basis of the charge thus collected, data regarding the visible radiation is generated. No bias voltage is applied between the second portion 11b of the first electrode 11 and the second portion 12b of the second electrode 12. Voltages such as a ground voltage and a power supply voltage are applied to the second portion 11b of the first electrode 11 and the second portion 12b of the second electrode 12. That is, the second portion 11b of the first electrode 11 and the second portion 12b of the second electrode 12 function as shield electrodes. The shield electrodes make it possible to prevent mixture of data based on near infrared radiation and data based on visible radiation.

### Modification 9

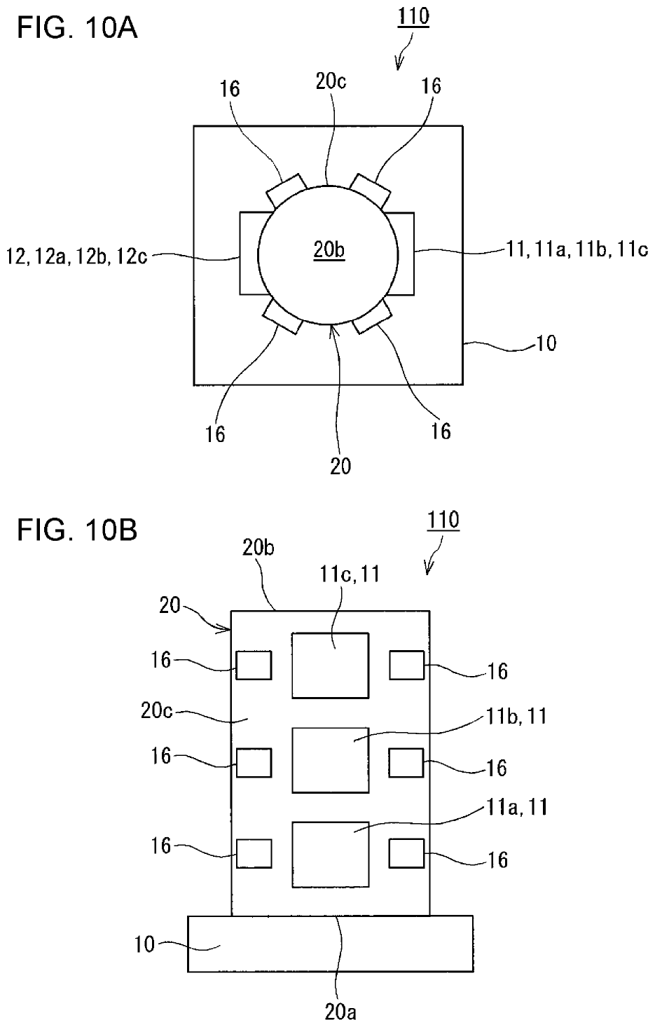

FIG. 10A shows a schematic cross-section of an optical sensor 110 according to Modification 9. FIG. 10B is a side view of the optical sensor 110 shown in FIG. 10A. The optical sensor 110 is equivalent to an example of improvement in the optical sensor 102 described with reference to FIG. 1D.

The optical sensor 110 includes a first electrode 11 and a second electrode 12. The first electrode 11 and the second electrode 12 are provided on a third surface 20c serving as at least one side surface of the photoelectric conversion layer 20. The shape of the photoelectric conversion layer 20 is not limited to a particular shape. The photoelectric conversion layer 20 has, for example, the shape of a circular column. The first electrode 11 includes a first portion 11a, a second portion 11b, and a third portion 11c. In the depth direction parallel with the depth of the photoelectric conversion layer 20, the first portion 11a, the second portion 11b, and the third portion 11c are separated from one another. The second electrode 12 includes a first portion 12a, a second portion 12b, and a third portion 12c. In the depth direction parallel with the depth of the photoelectric conversion layer 20, the first portion 12a, the second portion 12b, and the third portion 12c are separated from one another.

On the third surface 20c, a plurality of shield electrodes 16 are further provided. For example, four shield electrodes 16 are provided in correspondence with an electrode pair formed by the first portions 11a and 12a. Four shield electrodes 16 are provided in correspondence with an electrode pair formed by the second portions 11b and 12b. Four shield electrodes 16 are provided in correspondence with an electrode pair formed by the third portions 11c and 12c. In a side view (FIG. 10B) of the optical sensor 110, a pair of shield electrodes 16 are disposed on the right and left sides, respectively, of the first portion 11a of the first electrode 11. A pair of shield electrodes 16 are disposed on the right and left sides, respectively, of the second portion 11b of the first electrode 11. A pair of shield electrodes 16 are disposed on the right and left sides, respectively, of the third portion 11c of the first electrode 11. A pair of shield electrodes 16 are disposed on the right and left sides, respectively, of the first portion 12a of the second electrode 12. A pair of shield electrodes 16 are disposed on the right and left sides, respectively, of the second portion 12b of the second electrode 12. A pair of shield electrodes 16 are disposed on the right and left sides, respectively, of the third portion 12c of the second electrode 12. By accurately controlling electric potentials of these shield electrodes 16, a path for charge is formed on a straight line connecting the first electrode 11 with the second electrode 12. This results in making it possible to reduce charge that remains in the photoelectric conversion layer 20 when the optical sensor 110 is driven. The reduction of residual charge means a reduction of image retention in an imaging element including the optical sensor 110.

Next, a method for manufacturing an optical sensor of the present disclosure is described by taking, as an example, the optical sensor 108 described with reference to FIG. 9A.

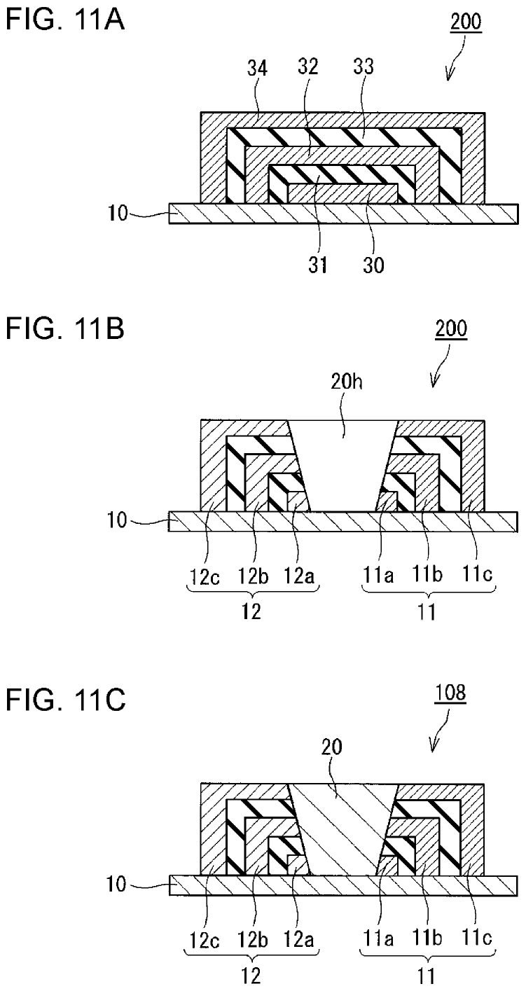

FIGS. 11A, 11B, and 11C show a process for manufacturing an optical sensor 108 of the present disclosure. As shown in FIG. 11A, first, a first electrode layer 30 is formed on the substrate 10, and the first electrode layer 30 is given a predetermined shape by patterning. The first electrode layer 30 is a portion that is to become the first portion 11a of the first electrode 11 and the first portion 12a of the second electrode 12. A first insulating layer 31 is formed on the first electrode layer 30, and the first insulating layer 31 is given a predetermined shape by patterning. Similarly, a second electrode layer 32, a second insulating layer 33, and a third electrode layer 34 are formed. The second electrode layer 32 is a portion that is to become the second portion 11b of the first electrode 11 and the second portion 12b of the second electrode 12. The third electrode layer 34 is a portion that is to become the third portion 11c of the first electrode 11 and the third portion 12c of the second electrode 12. By thus alternately forming the necessary number of electrode layers and insulating layers, a stacked structure 200 is fabricated. The order in which the electrode layer and the insulating layers are formed is not limited to the foregoing example. An insulating layer may be formed first on the substrate 10.

The electrode layers may be formed by a film-forming method such as sputtering, vacuum evaporation, ALD (atomic layer deposition), or CVD (chemical vapor deposition). The electrode layers may be formed by a printing process involving the use of a coatable electrode material. The patterning of the electrode layers may be performed by using a mask having an intended pattern at the time of film formation, or may be performed by photolithography. In a case where the electrode layers are formed by a printing process, the patterning may be performed, for example, by an inkjet method.

The insulating layers may be formed by a film-forming method such as sputtering, vacuum evaporation, ALD, or CVD. The insulating layers may be formed by a printing process involving the use of a coatable insulating material. The patterning of the insulating layers may be performed by using a mask having an intended pattern at the time of film formation, or may be performed by photolithography. In a case where the insulating layers are formed by a printing process, the patterning may be performed, for example, by an inkjet method.

As shown in FIG. 11B, next, a via hole 20h for the photoelectric conversion layer 20 is formed in the stacked structure 200. The via hole 20h may be formed, for example, by photolithography. That is, after a resist or a protective film has been formed on the stacked structure 200, a portion in which the via hole 20h is formed is exposed by photolithography. Next, the via hole 20h is formed by partially removing the electrode layers and the insulating layers by dry etching. After that, the resist or the protective film is removed.

As shown in FIG. 11C, finally, the photoelectric conversion layer 20 is formed by filling the via hole 20h with an organic semiconductor. An example of a method for filling the via hole 20h with an organic semiconductor include vacuum evaporation and a printing process. The via hole 20h may be filled with an organic semiconductor by covering a portion other than the via hole 20h with a mask and depositing the organic semiconductor. This gives an optical sensor 108 having an intended structure. The via hole 20h can alternatively be filled with an organic semiconductor by applying the organic semiconductor by a pattern-forming method such as an inkjet method or screen printing. It is alternatively possible to form the photoelectric conversion layer 20 by depositing an organic semiconductor all over an upper surface of the stacked structure 200 by a method such as vacuum evaporation or spin coating and then patterning the deposit by photolithography.

The manufacturing process of the present embodiment, according to which the electrodes are fabricated prior to the fabrication of the photoelectric conversion layer 20, makes it hard for the photoelectric conversion layer 20 to be damaged by electrode formation.

### Second Embodiment

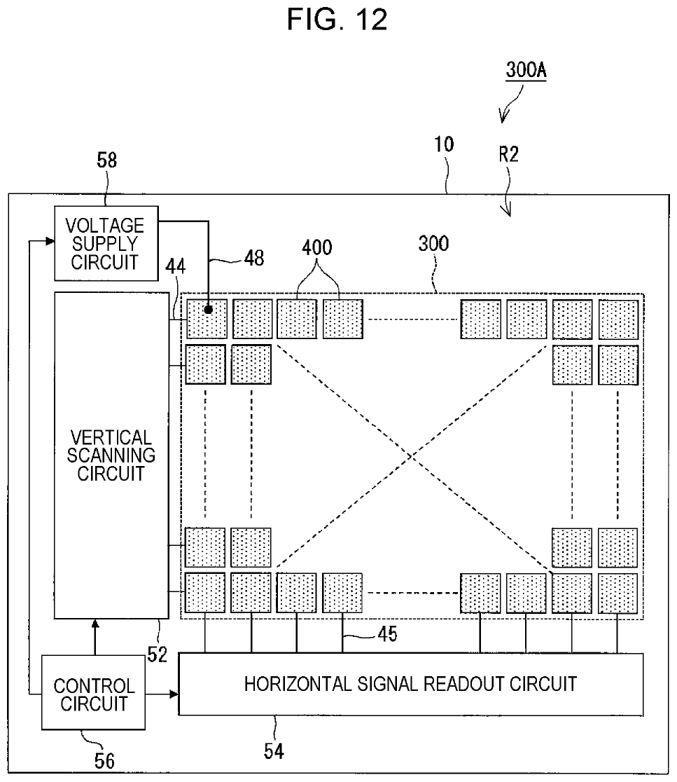

FIG. 12 shows a configuration of an imaging apparatus 300A according to a second embodiment of the present disclosure. The imaging apparatus 300A includes an imaging element 300. The imaging element 300 includes a substrate 10 and a plurality of pixels 400. The plurality of pixels 400 are provided on the substrate 10. Each of the pixels 400 is supported by the substrate 10. The pixels 400 may be partially constituted by the substrate 10.

Each of the plurality of pixels 400 includes any of the optical sensors described with reference to FIGS. 1 to 9B.

In FIG. 12, the pixels 400 are arranged in a plurality of rows and a plurality of columns, namely m rows and n columns. Note here that m and n each independently represent an integer greater than or equal to 1. The pixels 400 form an imaging region, for example, by being arranged two-dimensionally on the substrate 10.

The number and arrangement of the pixels 400 are not limited to a particular number or a particular arrangement. In FIG. 12, the center of each of the pixels 400 is located on a lattice point of a tetragonal lattice. The plurality of pixels 400 may be arranged so that the center of each of the pixels 400 is located on a lattice point of a triangular lattice, a hexagonal lattice, or other lattices. By arranging the pixels 400 one-dimensionally, the imaging element 300 may be used as a line sensor.

The imaging apparatus 300A has peripheral circuitry formed on the substrate 10.

The peripheral circuitry includes a vertical scanning circuit 52 and a horizontal signal readout circuit 54. The peripheral circuitry may additionally include a control circuit 56 and a voltage supply circuit 58. The peripheral circuitry may further include a signal processing circuit, an output circuit, or other circuits. Each of the circuits is provided on the substrate 10. The peripheral circuitry may be partially disposed on another substrate different from the substrate 10, on which the pixels 400 are formed.

The vertical scanning circuit 52 is also called “row scanning circuit”. Address signal lines 44 are provided separately in correspondence with each of the rows of pixels 400, and the address signal lines 44 are connected to the vertical scanning circuit 52. Signal lines provided separately in correspondence with each of the rows of pixels 400 are not limited to the address signal lines 44, and plural types of signal line may be connected to the vertical scanning circuit 52 separately for each of the rows of pixels 400. The horizontal signal readout circuit 54 is also called “column scanning circuit”. Vertical signal lines 45 are provided separately in correspondence with each of the columns of pixels 400, and the vertical signal lines 45 are connected to the horizontal signal readout circuit 54.

The control circuit 56 receives command data and clock signals from outside the imaging apparatus 300A and exercises overall control of the imaging apparatus 300A. Typically, the control circuit 56 has a timing generator and supplies driving signals to the vertical scanning circuit 52, the horizontal signal readout circuit 54, the voltage supply circuit 58, or other circuits. The control circuit 56 may be implemented as a microcontroller including one or more processors. The function of the control circuit 56 may be implemented by a combination of a general-purpose processing circuit and software, or may be implemented by hardware specialized in such processing.

The voltage supply circuit 58 supplies a predetermined voltage to each of the pixels 400 via a voltage line 48. The voltage supply circuit 58 is not limited to a particular power supply circuit, but may be a circuit that converts, into a predetermined voltage, a voltage supplied from a power supply such as a battery or a circuit that generates a predetermined voltage. The voltage supply circuit 58 may be a part of the aforementioned vertical scanning circuit 52. These circuits which constitute the peripheral circuitry may be disposed in a peripheral region R2 outside the imaging element 300.

An optical sensor of the present disclosure is applicable to an imaging apparatus, a receiving apparatus of a remote controller, or other apparatuses.

What is claimed is:

1. An optical sensor comprising:
a substrate;
a photoelectric conversion layer that has a first surface facing the substrate, a second surface located opposite the first surface, and at least one side surface connecting the first surface with the second surface, the photoelectric conversion layer being supported by the substrate;
a first electrode provided on the at least one side surface, the first electrode including a first portion and a second portion separated from the first portion, the second portion being closer to the second surface than the first portion is; and
a second electrode provided on the at least one side surface.

2. The optical sensor according to claim 1, wherein an area of the first portion of the first electrode is larger than an area of the second portion of the first electrode.

3. The optical sensor according to claim 1, wherein the second electrode includes a first portion and a second portion separated from the first portion of the second electrode, the second portion of the second electrode being closer to the second surface than the first portion of the second electrode is.

4. The optical sensor according to claim 3, wherein an area of the first portion of the second electrode is larger than an area of the second portion of the second electrode.

5. The optical sensor according to claim 1, wherein an angle formed by the at least one side surface and the first surface is larger than 90 degrees.

6. The optical sensor according to claim 1, wherein
the at least one side surface includes a third surface connecting the first surface with the second surface and a fourth surface connecting the first surface with the second surface, the fourth surface being different from the third surface,
the first electrode is provided on the third surface, and
the second electrode is provided on the fourth surface.

7. The optical sensor according to claim 6, wherein an angle formed by the third surface and the first surface is larger than 90 degrees.

8. The optical sensor according to claim 6, wherein an angle formed by the fourth surface and the first surface is larger than 90 degrees.

9. The optical sensor according to claim 6, wherein the third surface and the fourth surface are adjacent to each other.

10. The optical sensor according to claim 6, wherein
the at least one side surface further includes a fifth surface and a sixth surface,
the fifth surface is located between the third surface and the fourth surface and connects the first surface with the second surface, and
the sixth surface is different from the third surface, the fourth surface, and the fifth surface and connects the first surface with the second surface.

11. The optical sensor according to claim 1, wherein
the first electrode further includes a third portion separated from the second portion of the first electrode, the third portion of the first electrode being closer to the second surface than the second portion of the first electrode is,
the second electrode includes a first portion, a second portion, and a third portion, the second portion of the second electrode being separated from the first portion of the second electrode and being closer to the second surface than the first portion of the second electrode is, the third portion of the second electrode being separated from the second portion of the second electrode and being closer to the second surface than the second portion of the second electrode is, and
the second portion of the first electrode and the second portion of the second electrode function as shield electrodes.

12. An optical sensor comprising:
a substrate;
a photoelectric conversion layer that has a first surface facing the substrate, a second surface located opposite the first surface, and a third surface connecting the first surface with the second surface, the photoelectric conversion layer being supported by the substrate;
a first electrode provided on the third surface, the first electrode including a first portion and a second portion separated from the first portion, the second portion being closer to the second surface than the first portion is; and
a second electrode located within the photoelectric conversion layer.

13. The optical sensor according to claim 1, wherein the photoelectric conversion layer contains an organic material.

14. The optical sensor according to claim 1, wherein at all depth positions along a direction from the first surface toward the second surface, the photoelectric conversion layer has a hole-transporting ability and/or an electron-transporting ability.

15. The optical sensor according to claim 1, wherein the photoelectric conversion layer has electrical conductivity over a range from the first surface to the second surface.

16. The optical sensor according to claim 1, wherein
the photoelectric conversion layer converts light having a first wavelength into a first electric charge and converts light having a second wavelength into a second electric charge,
the first portion of the first electrode collects the first electric charge more than the second electric charge, and
the second portion of the first electrode collects the second electric charge more than the first electric charge.

17. The optical sensor according to claim 16, wherein an absorption coefficient of the photoelectric conversion layer at the second wavelength is higher than an absorption coefficient of the photoelectric conversion layer at the first wavelength.
